(19) United States
(12) Patent Application Publication
(10) Pub. No.: US 2015/0292079 A1
(43) Pub. Date: Oct. 15, 2015

(54) VAPORIZATION SOURCE ASSEMBLY OF OLED VAPOR DEPOSITION MACHINE

(71) Applicant: SHENZHEN CHINA STAR OPTOELECTRONICS TECHNOLOGY CO., LTD., Shenzhen, Guangdong (CN)

(72) Inventor: Qinghua Zou, Shenzhen (CN)

(21) Appl. No.: 14/345,935

(22) PCT Filed: Jan. 21, 2014
(86) PCT No.: PCT/CN2014/070933

§ 371 Date: Mar. 19, 2014

(30) Foreign Application Priority Data
Dec. 27, 2013 (CN) 201310739659.4

(51) Int. Cl. C23C 14/24

(52) U.S. Cl. CPC C23C 14/243

(57) ABSTRACT

The present invention provides a vaporization source assembly of an OLED vapor deposition machine, which includes: a carrying platform (2), a plurality of vapor deposition crucibles (4) mounted on the carrying platform (2), and an unblocking mechanism (6) mounted on the carrying platform (2). The unblocking mechanism (6) includes a vertical arm (62), a horizontal arm (64) perpendicularly connected to an end of the vertical arm (62), and a detection pin (66) perpendicularly connected to a free end of the horizontal arm (64). The vertical arm (62) is mounted, in an extendible/retractable manner, on the carrying platform (2) and is rotatable with respect to the carrying platform (2). The horizontal arm (64) and the vertical arm (62) control the detection pin (66) to carry out unblocking operations on the vapor outlet holes of the vapor deposition crucibles (4). The vaporization source assembly of the OLED vapor deposition machine provided by the present invention uses the arrangement of the unblocking mechanism to carry out an unblocking operation on the vapor outlet hole of a vapor deposition crucible without opening a chamber of a vapor deposition machine so as to save time and thus effectively increasing the unblocking efficiency and improving the utilization of the vapor deposition machine.

### BACKGROUND OF THE INVENTION

1. Field of the Invention

The present invention relates to the field of vapor deposition processes, and in particular to a vaporization source assembly of an OLED (Organic Light-Emitting Diode) vapor deposition machine.

2. The Related Arts

As a new generation solid-state luminescent display technology, OLED has the advantages of ultra-thinness, high response, high contrast, and low power consumption over liquid crystal displays and has been recently under fast progress for industrialization. Samsung® Group has already used AMOLED display screens on their own smart phones and gain an excellent market.

Referring to FIG. 1, a schematic view is given to show the structure of an OLED, which comprises: a substrate 100, an OLED device 300 formed on the substrate 100, and a package lid 500 laminated to the substrate 100. The OLED device 300 comprises an anode 302 formed on the substrate 100, an organic function layer 304 formed on the anode 302, and a cathode 306 formed on the organic function layer 304. The anode 302 and the cathode 306 excite the organic function layer 304 to realize displaying.

The organic function layer of an OLED is generally composed of three function layers, which are respectively a hole transport layer (HTL), an emissive layer (EML), and an electron transport layer (ETL). Each of the function layers can be made up of a single layer or more than one layer. For example, the hole transport layer may sometimes further divided into a hole injection layer and a hole transport layer and the electron transport layer can be further divided into an electron injection layer and an electron transport layer. However, they are of similar functions and are collectively referred to as the hole transport layer or the electron transport layer.

The current main-stream manufacturing technique and process is vapor deposition, which is to heat organic small-molecule material in a vacuum chamber to have it sublimated or molten and vaporized into vapor of the material that is deposited through an opening formed in a metal mask onto a glass substrate.

The thickness and doping ratio of each layer of an OLED device have significant influence on the performance of the device. To make the thickness and doping ratio of the organic material deposited on every part of a substrate homogeneous, a spot vaporization source based vapor deposition machine is structured to have the organic material deposited with the substrate set in a condition of being rotated. However, the material utilization of the spot vaporization source based vapor deposition machine is extremely low, approximately 5%. A line vaporization source based vapor deposition machine, which has been developed later, is capable of making the homogeneity of organic material film thickness better and also increases the material utilization up to around 20%.

Both the spot vaporization source based vapor deposition machine and the line vaporization source based vapor deposition machine suffer the potential risk and also phenomenon of material jamming of holes. Due to the factors of crucible, temperature, and material, the organic material vapor may get condensed at a vapor outlet hole, making the vapor outlet hole gradually jammed, so that the rate is gradually slowed down and eventually complete blocking results. In a time-extended operation of coating, the organic material deposited on a source shutter may get gradually thickened and may sometimes get peeling off so that once falling on the vapor outlet hole, it directly blocks the organic material vapor. Localized abnormalities of film thickness or doping ratio of the organic material may result, making the performance and light color of the OLED abnormal. In such a situation, the OLED material must be cooled down to room temperature and the chamber of the vapor deposition machine opened to clear up the hole blocked vaporization source. After that, the chamber of the vapor deposition machine can be closed again and evacuated to 1.0E-5 Pa and then the organic material can be heated up again to have the coating rate stabilized. It often takes tens of hours for such a process and may severely affect the production project.

### SUMMARY OF THE INVENTION

An object of the present invention is to provide a vaporization source assembly of an OLED vapor deposition machine, which can unblock a vapor outlet hole of a the vaporization source without opening a chamber of the vapor deposition machine so as to greatly shortening the time period for unblocking thereby greatly improving utilization of the vapor deposition machine.

To achieve the above object, the present invention provides a vaporization source assembly of an OLED vapor deposition machine, which comprises: a carrying platform, a plurality of vapor deposition crucibles mounted on the carrying platform, and an unblocking mechanism mounted on the carrying platform. The unblocking mechanism comprises a vertical arm, a horizontal arm perpendicularly connected to an end of the vertical arm, and a detection pin perpendicularly connected to a free end of the horizontal arm. The vertical arm is mounted, in an extendible/retractable manner, on the carrying platform and rotatable with respect to the carrying platform, whereby the horizontal arm and the vertical arm control the detection pin to carry out unblocking operations on vapor outlet holes of the vapor deposition crucibles.

The vertical arm comprises a first vertical section and a second vertical section connected to the first vertical section. The first vertical section is mounted, in a rotatable manner, on the carrying platform. The second vertical section is extendable/retractable with respect to the first vertical section. The horizontal arm is connected to a free end of the second vertical section.

The horizontal arm comprises a first horizontal section connected to the second vertical section and a second horizontal section connected to the first horizontal section. The second horizontal section is extendible/retractable with respect to the first horizontal section. The detection pin is mounted to a free end of the second horizontal section.

The rotation and extension/retraction are achieved with servomotors or pneumatic valves.

Multiple unblocking mechanisms are provided, of which the number corresponds to the number of the vapor deposition crucibles. The horizontal arm comprises a third horizontal section connected to the second vertical section. The detection pin is mounted to a free end of the third horizontal section.

The unblocking mechanism further comprises a base. The base is mounted on the carrying platform. The vertical arm is mounted on the base in a slidable manner. The vertical arm is rotatable with respect to the base.

The base comprises a slide channel formed thereon. The vertical arm comprises a slide corresponding to the slide channel. The slide is slidable in the slide channel to cause the vertical arm to slide with respect to the base.

The sliding is achieved with a servomotor.

The unblocking mechanism further comprises a light source and an image sensor mounted to the free end of the horizontal arm for observation of a condition of blocking/unblocking of the vapor outlet holes of the vapor deposition crucibles.

The vaporization source assembly of the OLED vapor deposition machine further comprises a display device electrically connected to the image sensor.

The present invention also provides a vaporization source assembly of an OLED vapor deposition machine, which comprises: a carrying platform, a plurality of vapor deposition crucibles mounted on the carrying platform, and an unblocking mechanism mounted on the carrying platform, the unblocking mechanism comprising a vertical arm, a horizontal arm perpendicularly connected to an end of the vertical arm, and a detection pin perpendicularly connected to a free end of the horizontal arm, the vertical arm being mounted, in an extendible/retractable manner, on the carrying platform and rotatable with respect to the carrying platform, whereby the horizontal arm and the vertical arm control the detection pin to carry out unblocking operations on vapor outlet holes of the vapor deposition crucibles;

wherein the vertical arm comprises a first vertical section and a second vertical section connected to the first vertical section, the first vertical section being mounted, in a rotatable manner, on the carrying platform, the second vertical section being extendable/retractable with respect to the first vertical section, the horizontal arm being connected to a free end of the second vertical section;

wherein the horizontal arm comprises a first horizontal section connected to the second vertical section and a second horizontal section connected to the first horizontal section, the second horizontal section being extendible/retractable with respect to the first horizontal section, the detection pin being mounted to a free end of the second horizontal section;

wherein the rotation and extension/retraction are achieved with servomotors or pneumatic valves; and

wherein the unblocking mechanism further comprises a base, the base being mounted on the carrying platform, the vertical arm being mounted on the base in a slidable manner, the vertical arm being rotatable with respect to the base.

The base comprises a slide channel formed thereon. The vertical arm comprises a slide corresponding to the slide channel. The slide is slidable in the slide channel to cause the vertical arm to slide with respect to the base.

The sliding is achieved with a servomotor.

The unblocking mechanism further comprises a light source and an image sensor mounted to the free end of the horizontal arm for observation of a condition of blocking/unblocking of the vapor outlet holes of the vapor deposition crucibles.

The vaporization source assembly of the OLED vapor deposition machine further comprises a display device electrically connected to the image sensor.

The efficacy of the present invention is that the present invention provides a vaporization source assembly of an OLED vapor deposition machine, which comprises the arrangement of an unblocking mechanism to carry out an unblocking operation on a vapor outlet hole of a vapor deposition crucible without opening a chamber of a vapor deposition machine so as to effectively shorten the unblocking time and improve the utilization of the vapor deposition machine. Further, the unblocking mechanism comprises a horizontal arm and a vertical arm both of which are of such a structure as to be adjustable for the lengths thereof so that the unblocking mechanism is not only applicable to a vapor deposition machine of which the vapor deposition crucibles are arranged on the carrying platform in a uniform manner and is also applicable to a vapor deposition machine of which the vapor deposition crucibles are arranged on the carrying platform in a non-uniform manner, making it applicable to a wide range. Further, the horizontal arm has a free end to which a light source and an image sensor may be mounted with the image sensor being in electrical connection with the display device so as to allow for observation of the condition of the vapor outlet hole of each vapor deposition crucibles. Determination can thus be made according to the result of observation as to whether an unblocking operation is to be performed thereby ensuring the effect of vapor deposition.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a schematic view showing the structure of a conventional OLED (Organic Light-Emitting Diode);

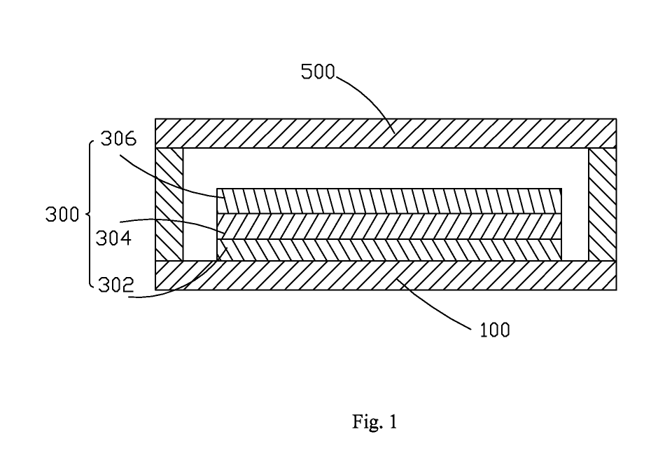

FIG. 2 is a schematic view showing a first embodiment of a vaporization source assembly of an OLED vapor deposition machine according to the present invention;

FIG. 3 is a schematic perspective view showing an unblocking mechanism of FIG. 2;

FIG. 4 is a schematic view showing a second embodiment of the vaporization source assembly of the OLED vapor deposition machine according to the present invention;

FIG. 5 is a schematic perspective view showing an unblocking mechanism of FIG. 4;

FIG. 6 is a schematic view showing a third embodiment of the vaporization source assembly of the OLED vapor deposition machine according to the present invention; and

FIG. 7 is a schematic perspective view showing an unblocking mechanism of FIG. 6.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

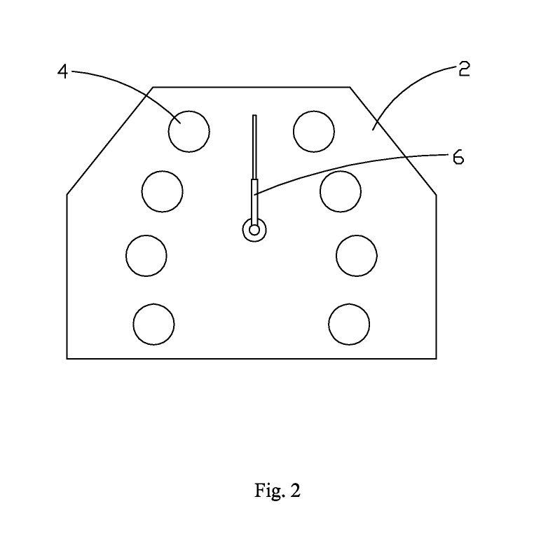

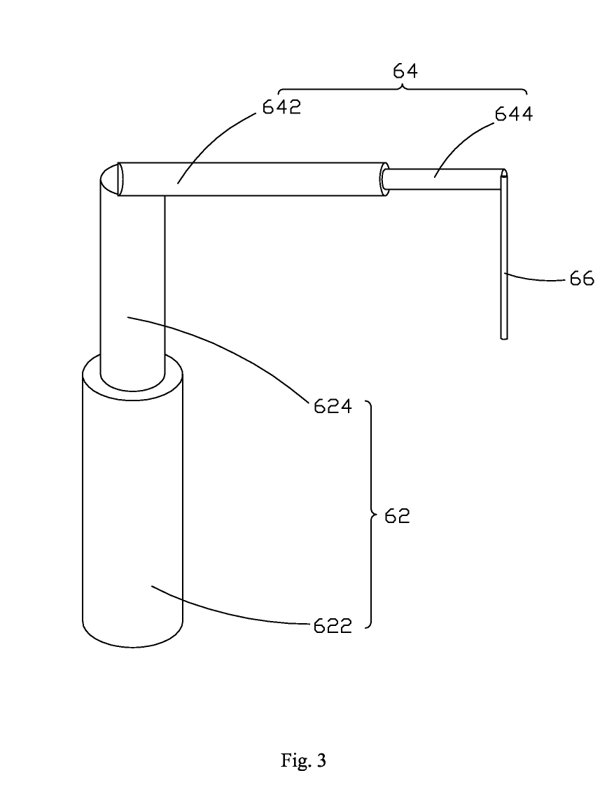

Referring to FIGS. 2 and 3, the present invention provides a vaporization source assembly of an OLED (Organic Light-Emitting Diode) vapor deposition machine, which comprises: a carrying platform 2, a plurality of vapor deposition crucibles 4 mounted on the carrying platform 2, and an unblocking mechanism 6 mounted on the carrying platform 2. The unblocking mechanism 6 comprises a vertical arm 62, a horizontal arm 64 perpendicularly connected to an end of the vertical arm 62, and a detection pin 66 perpendicularly connected to a free end of the horizontal arm 64. The vertical arm 62 is mounted, in an extendible/retractable manner, on the carrying platform 2 and is rotatable with respect to the carrying platform 2. The horizontal arm 64 and the vertical arm 62 control the detection pin 66 to carry out unblocking operations on the vapor outlet holes of the vapor deposition crucibles 4, whereby the unblocking operations of the vapor outlet holes of the vapor deposition crucibles 4 can be carried out without opening a chamber of the vapor deposition machine so as to effectively shorten the unblocking time and the improve the utilization of the vapor deposition machine.

Specifically, referring to FIG. 3, in the instant embodiment, the carrying platform 2 is of a polygonal shape and the vapor deposition crucibles 4 are disturbed on the carrying platform 2 in a non-uniform manner so as to form spot vaporization sources. The vertical arm 62 comprises a first vertical section 622 and a second vertical section 624 connected to the first vertical section 622. The first vertical section 622 is mounted, in a rotatable manner, on the carrying platform 2. The second vertical section 624 is extendable/retractable with respect to the first vertical section 622. The horizontal arm 64 is connected to a free end of the second vertical section 624. Through the extension/retraction of the second vertical section 624, a vertical distance between the horizontal arm 64 and the vapor deposition crucibles 4 can be controlled, thereby achieving control of a vertical distance between the detection pin 66 and the vapor deposition crucibles 4. For example, when it needs to unblock the vapor outlet holes of a vapor deposition crucible 4, the second vertical section 624 is caused to extend first to allow the detection pin 66 to suspend exactly above the vapor outlet hole of the vapor deposition crucibles 4. Then, the second vertical section 624 is caused to retract, allowing the detection pin 66 to insert, from the top side, into the vapor outlet hole of the vapor deposition crucible 4 so as to achieve unblocking of the vapor outlet hole of the vapor deposition crucible 4. The operation is simple and the unblocking efficiency is high.

Further, in the instant embodiment, the horizontal arm 64 comprises a first horizontal section 642 connected to the second vertical section 624 and a second horizontal section 644 connected to the first horizontal section 642. The second horizontal section 644 is extendible/retractable with respect to the first horizontal section 642. The detection pin 66 is mounted to a free end of the second horizontal section 644. Through the extension/retraction of the second horizontal section 644, a horizontal distance between the detection pin 66 and the vapor deposition crucibles 4 can be controlled to achieve unblocking for the vapor outlet holes of the multiple vapor deposition crucibles 4. For example, when it needs to unblock the vapor outlet hole of a vapor deposition crucible 4, the second vertical section 624 is caused to extend first to have the detection pin 66 suspending above the vapor deposition crucibles 4. Then, the first vertical section 622 is rotated to have the detection pin 66 suspending above the vapor deposition crucible 4 to be unblocked. And, then, the second horizontal section 644 is caused to extend or retract to have the detection pin 66 suspending exactly above the vapor outlet hole of the vapor deposition crucible 4 to be unblocked. Finally, the second vertical section 624 is caused to retract to have the detection pin 66 inserted, from the top side, into the vapor outlet hole of the vapor deposition crucible 4, thereby achieving unblocking of the vapor outlet hole of the vapor deposition crucible 4. Since the length of the horizontal arm 64 is extendible/retractable, besides being applicable to a vapor deposition machine having a carrying platform 2 on which vapor deposition crucibles 4 are not arranged in an uniform manner, the unblocking mechanism 6 is also applicable to a vapor deposition machine comprising a carrying platform 2 on which vapor deposition crucibles 4 are arranged in a non-uniform manner, making it applicable to a wider range.

It is noted that in the present invention, the rotation and extension/retraction are achieved with servomotors or pneumatic valves. Specific ways for realizing the operations can be achieved with known art. For example, when rotation and extension/retraction are realized with pneumatic valves, the first horizontal section 642 and the first vertical section 622 can be each made in the form of an enclosed cylinder and the second horizontal section 644 and the second vertical section 624 are respectively coupled via pistons to the first horizontal section 642 and the first vertical section 622 to show a form of a cylinder. Through control of internal air volumes of the first horizontal section 642 and the first vertical section 622 by the pneumatic valves, extension/retraction of the second horizontal section 644 and the second vertical section 624 with respect to the first horizontal section 642 and the first vertical section 622 can be realized. For rotation and extension/retraction realized with servomotors, they can be achieved with various ways of driving, such as belt transmission and gear transmission, all these realizing the above described technical effect.

Preferably, the unblocking mechanism 6 further comprises a light source (not shown) and an image sensor (not shown) mounted to the horizontal arm 64 for observation of the condition of blocking and unblocking of the vapor outlet holes of the vapor deposition crucibles 4. The vaporization source assembly of the OLED vapor deposition machine may further comprise a display device (not shown) electrically connected to the image sensor, so that the condition of blocking and unblocking of the vapor outlet holes of the vapor deposition crucibles 4 can be displayed with the display device.

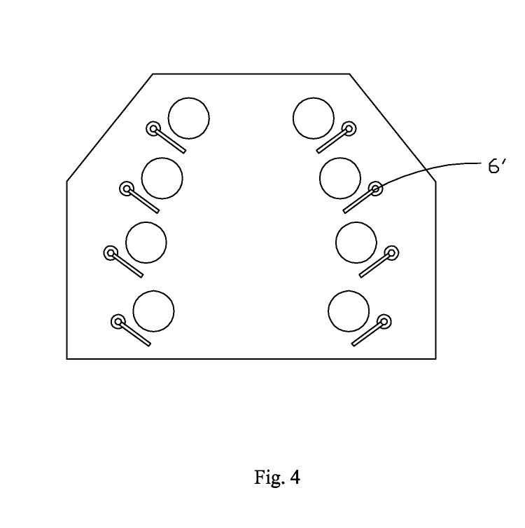

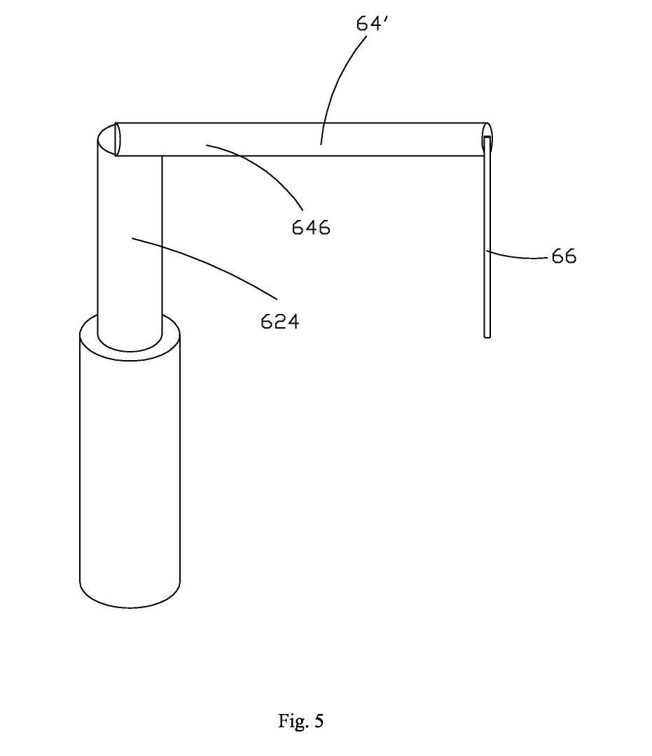

Referring to FIGS. 4 and 5, which are schematic views showing a second embodiment of the vaporization source assembly of the OLED vapor deposition machine according to the present invention, in the instant embodiment, multiple unblocking mechanisms 6′ are provided, of which the number corresponds to the number of the vapor deposition crucibles 4 for the purposes of preventing contamination among the vapor deposition materials and also to make a braking device simple. The unblocking mechanisms 6′ are arranged to correspond to the vapor deposition crucibles 4 so that it is not necessary for the lengths of the horizontal arms 64′ to be adjustable, whereby the horizontal arms 64′ each comprises a single third horizontal section 646 connected to the second vertical section 624 and the detection pin 66 is mounted to a free end of the third horizontal section 646. When it is desired to unblock the vapor outlet hole of a vapor deposition crucible 4, it only needs to control the second vertical section 624 to extend/retract with respect to the first vertical section 622 to achieve unblocking of the vapor outlet hole of the vapor deposition crucible 4.

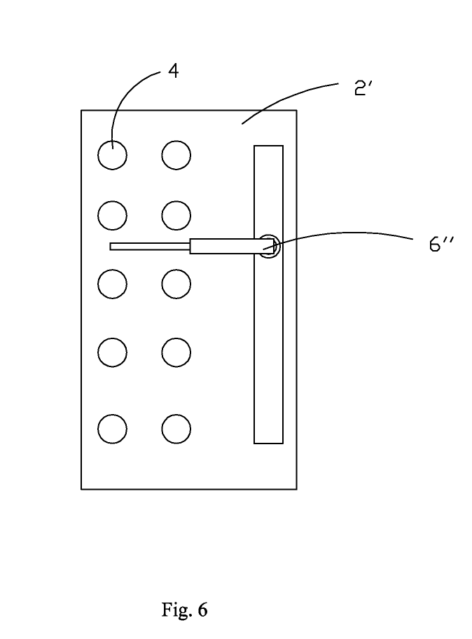

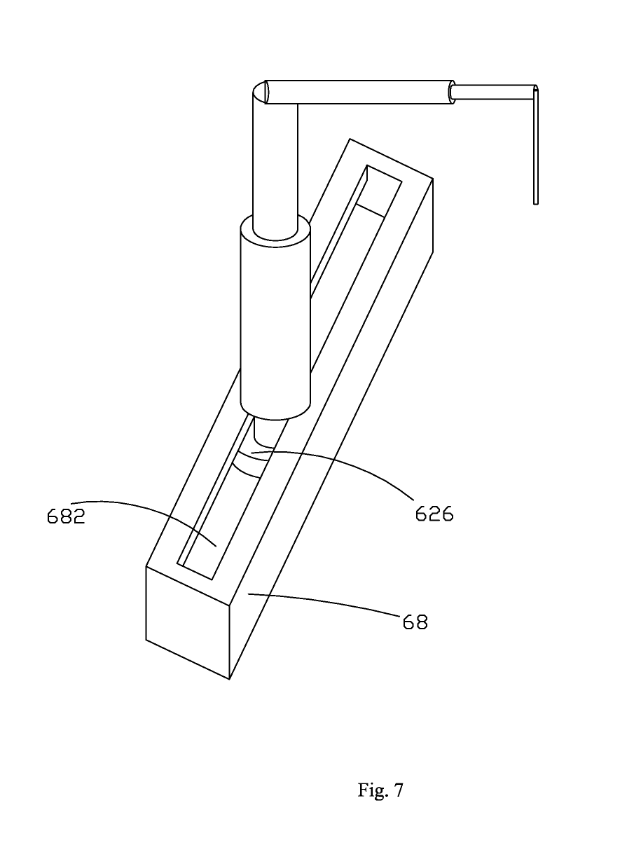

Referring to FIGS. 6 and 7, which schematically show a third embodiment of the vaporization source assembly of the OLED vapor deposition machine according to the present invention, in the instant embodiment, the carrying platform 2′ is rectangular in shape and the vapor deposition crucibles 4 are mounted in a linear arrangement on the carrying platform 2′ to form a line vaporization source. The unblocking mechanism 6″ further comprises a base 68. The base 68 is mounted on the carrying platform 2′ and the vertical arm 62 is mounted, in a slidable manner, on the base 68. Further, the vertical arm 62 is mounted, in a rotatable manner, on the base 68. In the instant embodiment, the sliding is achieved with a servomotor.

Specifically, referring to FIG. 7, the base 68 may comprise a slide channel 682 formed thereon. The vertical arm 62 is provided with a slide 626 and the slide 626 can be driven by the servomotor to slide within the slide channel 682 so as to cause the vertical arm 62 to slide with respect to the base 68. Further, the slide 626 can be of a cylindrical shape, allowing it to rotate with respect to the base 68 as being driven by a servomotor so as to achieve unblocking of the vapor outlet holes of the vapor deposition crucible 4 at various locations.

In summary, the present invention provides a vaporization source assembly of an OLED vapor deposition machine, which comprises the arrangement of an unblocking mechanism to carry out an unblocking operation on a vapor outlet hole of a vapor deposition crucible without opening a chamber of a vapor deposition machine so as to effectively shorten the unblocking time and improve the utilization of the vapor deposition machine. Further, the unblocking mechanism comprises a horizontal arm and a vertical arm both of which are of such a structure as to be adjustable for the lengths thereof so that the unblocking mechanism is not only applicable to a vapor deposition machine of which the vapor deposition crucibles are arranged on the carrying platform in a uniform manner and is also applicable to a vapor deposition machine of which the vapor deposition crucibles are arranged on the carrying platform in a non-uniform manner, making it applicable to a wide range. Further, the horizontal arm has a free end to which a light source and an image sensor may be mounted with the image sensor being in electrical connection with the display device so as to allow for observation of the condition of the vapor outlet hole of each vapor deposition crucibles. Determination can thus be made according to the result of observation as to whether an unblocking operation is to be performed thereby ensuring the effect of vapor deposition.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A vaporization source assembly of an OLED (Organic Light-Emitting Diode) vapor deposition machine, comprising: a carrying platform, a plurality of vapor deposition crucibles mounted on the carrying platform, and an unblocking mechanism mounted on the carrying platform, the unblocking mechanism comprising a vertical arm, a horizontal arm perpendicularly connected to an end of the vertical arm, and a detection pin perpendicularly connected to a free end of the horizontal arm, the vertical arm being mounted, in an extendible/retractable manner, on the carrying platform and rotatable with respect to the carrying platform, whereby the horizontal arm and the vertical arm control the detection pin to carry out unblocking operations on vapor outlet holes of the vapor deposition crucibles.

2. The vaporization source assembly of the OLED vapor deposition machine as claimed in claim 1, wherein the vertical arm comprises a first vertical section and a second vertical section connected to the first vertical section, the first vertical section being mounted, in a rotatable manner, on the carrying platform, the second vertical section being extendable/retractable with respect to the first vertical section, the horizontal arm being connected to a free end of the second vertical section.

3. The vaporization source assembly of the OLED vapor deposition machine as claimed in claim 2, wherein the horizontal arm comprises a first horizontal section connected to the second vertical section and a second horizontal section connected to the first horizontal section, the second horizontal section being extendible/retractable with respect to the first horizontal section, the detection pin being mounted to a free end of the second horizontal section.

4. The vaporization source assembly of the OLED vapor deposition machine as claimed in claim 3, wherein the rotation and extension/retraction are achieved with servomotors or pneumatic valves.

5. The vaporization source assembly of the OLED vapor deposition machine as claimed in claim 2, wherein multiple unblocking mechanisms are provided, of which the number corresponds to the number of the vapor deposition crucibles, the horizontal arm comprising a third horizontal section connected to the second vertical section, the detection pin being mounted to a free end of the third horizontal section.

6. The vaporization source assembly of the OLED vapor deposition machine as claimed in claim 3, wherein the unblocking mechanism further comprises a base, the base being mounted on the carrying platform, the vertical arm being mounted on the base in a slidable manner, the vertical arm being rotatable with respect to the base.

7. The vaporization source assembly of the OLED vapor deposition machine as claimed in claim 6, wherein the base comprises a slide channel formed thereon, the vertical arm comprising a slide corresponding to the slide channel, the slide being slidable in the slide channel to cause the vertical arm to slide with respect to the base.

8. The vaporization source assembly of the OLED vapor deposition machine as claimed in claim 7, wherein the sliding is achieved with a servomotor.

9. The vaporization source assembly of the OLED vapor deposition machine as claimed in claim 1, wherein the unblocking mechanism further comprises a light source and an image sensor mounted to the free end of the horizontal arm for observation of a condition of blocking/unblocking of the vapor outlet holes of the vapor deposition crucibles.

10. The vaporization source assembly of the OLED vapor deposition machine as claimed in claim 9 further comprising a display device electrically connected to the image sensor.

11. A vaporization source assembly of an OLED (Organic Light-Emitting Diode) vapor deposition machine, comprising: a carrying platform, a plurality of vapor deposition crucibles mounted on the carrying platform, and an unblocking mechanism mounted on the carrying platform, the unblocking mechanism comprising a vertical arm, a horizontal arm perpendicularly connected to an end of the vertical arm, and a detection pin perpendicularly connected to a free end of the horizontal arm, the vertical arm being mounted, in an extendible/retractable manner, on the carrying platform and rotatable with respect to the carrying platform, whereby the horizontal arm and the vertical arm control the detection pin to carry out unblocking operations on vapor outlet holes of the vapor deposition crucibles;
wherein the vertical arm comprises a first vertical section and a second vertical section connected to the first vertical section, the first vertical section being mounted, in a rotatable manner, on the carrying platform, the second vertical section being extendable/retractable with respect to the first vertical section, the horizontal arm being connected to a free end of the second vertical section;
wherein the horizontal arm comprises a first horizontal section connected to the second vertical section and a second horizontal section connected to the first horizontal section, the second horizontal section being extendible/retractable with respect to the first horizontal section, the detection pin being mounted to a free end of the second horizontal section;
wherein the rotation and extension/retraction are achieved with servomotors or pneumatic valves; and
wherein the unblocking mechanism further comprises a base, the base being mounted on the carrying platform, the vertical arm being mounted on the base in a slidable manner, the vertical arm being rotatable with respect to the base.

12. The vaporization source assembly of the OLED vapor deposition machine as claimed in claim 11, wherein the base comprises a slide channel formed thereon, the vertical arm comprising a slide corresponding to the slide channel, the slide being slidable in the slide channel to cause the vertical arm to slide with respect to the base.

13. The vaporization source assembly of the OLED vapor deposition machine as claimed in claim 12, wherein the sliding is achieved with a servomotor.

14. The vaporization source assembly of the OLED vapor deposition machine as claimed in claim 11, wherein the unblocking mechanism further comprises a light source and an image sensor mounted to the free end of the horizontal arm for observation of a condition of blocking/unblocking of the vapor outlet holes of the vapor deposition crucibles.

15. The vaporization source assembly of the OLED vapor deposition machine as claimed in claim 14 further comprising a display device electrically connected to the image sensor.
